(19) United States
(12) Patent Application Publication
(10) Pub. No.: US 2025/0176303 A1
(43) Pub. Date: May 29, 2025

(54) SEMICONDUCTOR APPARATUS, MANUFACTURING METHOD, AND DEVICE

(71) Applicant: CANON KABUSHIKI KAISHA, Tokyo (JP)

(72) Inventor: YOSHIEI TANAKA, Tokyo (JP)

(21) Appl. No.: 18/952,920

(22) Filed: Nov. 19, 2024

(30) Foreign Application Priority Data
Nov. 27, 2023 (JP) 2023-200144

(51) Int. Cl. H01L 27/146

(52) U.S. Cl. CPC H10F 39/811; H10F 39/026; H10F 39/8037

(57) ABSTRACT

A semiconductor apparatus includes a semiconductor layer including a first surface, an element region, and an end portion, a wiring layer, an insulating member, a first plug including a conductor, disposed between the first surface and the wiring layer and disposed between the element region and the insulating member in a planar view, and a second plug including a conductor, disposed between the first surface and the wiring layer and disposed between the end portion and the insulating member in a planar view. The first plug and the second plug are electrically connected via the wiring layer. The conductor included in the first plug is connected to a first semiconductor region of a first conductivity type disposed in the semiconductor layer. The first semiconductor region is disposed inside a second semiconductor region of a second conductivity type disposed in the semiconductor layer.

### BACKGROUND

### Field

The present disclosure relates to a semiconductor apparatus, a manufacturing method, and a device.

### Description of the Related Art

With the increase in the integration of semiconductor devices, there has been a trend of downsizing transistors and other semiconductor elements to further increase the mounting density. In recent years, for example, stacked back-illuminated solid-state image sensors have been in widespread use. The sensor is composed of a pixel board on which pixels are formed and a control board on which a control circuit that performs pixel control and pixel signal processing is formed, the boards being stacked.

Japanese Patent Application Laid-Open No. 2020-065016 discusses a technique for forming a guard ring along the outer periphery of a semiconductor chip to improve the reliability of a semiconductor apparatus. The guard ring is formed of an isolation region with an embedded insulating film and a wiring structure including a plurality of wiring layers and a plurality of stacked insulators. Such a configuration can suffer damage to elements and a guard ring in the semiconductor layer in manufacturing and operation due to the influence of static electricity.

### SUMMARY

According to an aspect of the present disclosure, a semiconductor apparatus includes a semiconductor layer comprising a first surface, an element region, and an end portion, a wiring layer disposed on the side of the first surface, an insulating member disposed between the element region and the end portion in a planar view with respect to the first surface, and configured to penetrate through the semiconductor layer, a first plug including a conductor, disposed between the first surface and the wiring layer, and disposed between the element region and the insulating member in a planar view with respect to the first surface, and a second plug including a conductor, disposed between the first surface and the wiring layer and disposed between the end portion and the insulating member in a planar view with respect to the first surface. The first plug and the second plug are electrically connected via the wiring layer. The conductor included in the first plug is connected to a first semiconductor region of a first conductivity type disposed in the semiconductor layer. The first semiconductor region is disposed inside a second semiconductor region of a second conductivity type disposed in the semiconductor layer.

Further features of the present disclosure will become apparent from the following description of exemplary embodiments with reference to the attached drawings.

### BRIEF DESCRIPTION OF THE DRAWINGS

FIG. 1 is a schematic view illustrating the configuration of a semiconductor apparatus according to a first exemplary embodiment.

FIG. 2 is another schematic view illustrating the configuration of the semiconductor apparatus according to the first exemplary embodiment.

FIG. 3 is a schematic view illustrating a moisture-resistant structure according to the first exemplary embodiment.

FIGS. 4A and 4B illustrate an issue in the first exemplary embodiment.

FIG. 5 is a table illustrating polarities of semiconductor layers according to the first exemplary embodiment.

FIGS. 6A to 6D are schematic views illustrating configurations of the moisture-resistant structure according to the first exemplary embodiment.

FIG. 7 is a schematic view illustrating the configuration of a semiconductor apparatus according to a second exemplary embodiment.

FIG. 8 is a schematic view illustrating the configuration of a semiconductor apparatus according to a third exemplary embodiment.

FIGS. 9A to 9C are schematic views illustrating configurations of a device according to a fourth exemplary embodiment.

### DESCRIPTION OF THE EMBODIMENTS

The following exemplary embodiments are intended to embody the technical concept of the present disclosure but not intended to limit the present disclosure. In each drawing, sizes and positional relations of members may be emphasized to clarify the descriptions. In the following descriptions, like numbers refer to like components, and redundant descriptions thereof may be omitted.

Exemplary embodiments of the present disclosure will be described in detail with reference to the accompanying drawings. The following descriptions use terms indicating specific directions or positions (e.g., “upper”, “lower”, “right”, and “left”, and other terms including these terms) as appropriate. For example, when a semiconductor apparatus is a photoelectric conversion apparatus, the semiconductor layer has a first surface and a second surface as the light incident surface opposite to the first surface. In the descriptions of the following exemplary embodiments, the word “upper” refers to the direction from the second surface to the first surface in the semiconductor layer. The use of these terms is intended to facilitate the understanding of exemplary embodiments described with reference to the drawings. The technical scope of the present disclosure is not limited by the meanings of these terms.

In the present specification, the planar view refers to viewing from a direction perpendicular to the first surface of the semiconductor layer. The cross-sectional view refers to viewing a cross-section in a direction perpendicular to the first surface of the semiconductor layer. If the light incident surface of the semiconductor layer is a macroscopically coarse surface, the planar view is defined with reference to the light incident surface of the semiconductor layer when macroscopically viewed.

In the present specification, the terms “N type” and “P type” simply used mean the net type obtained by the deduction of the value compensated by the impurity of the opposite conductivity type. For example, a region where the P-type additive impurity density is higher than the N-type additive impurity density is a P-type semiconductor region. Conversely, a region where the N-type additive impurity density is higher than the P-type additive impurity density is an N-type semiconductor region.

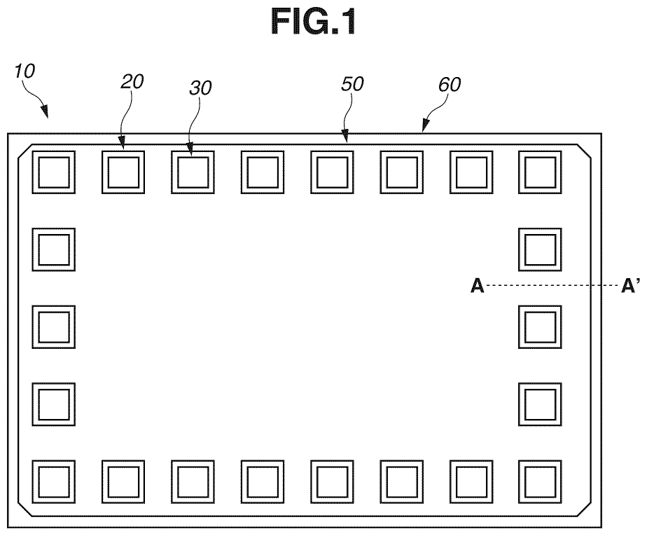

A first exemplary embodiment will be described with reference to FIGS. 1 to 5. According to the present exemplary embodiment, a stacked back-illuminated Complementary Metal Oxide Semiconductor (CMOS) sensor will be described as an example of a semiconductor apparatus. However, each exemplary embodiment is not limited thereto but is also applicable to other examples of semiconductor apparatuses. For example, the semiconductor apparatus can be a front-illuminated CMOS sensor or a Single Photon Avalanche Diode (SPAD) sensor. Each exemplary embodiment can also be applicable to semiconductor apparatuses other than image sensors, for example, a ranging device (a device for distance measurement using focal point detection or Time Of Flight [TOF]), and an exposure meter (a device for measuring the quantity of incident light).

FIG. 1 is a plan view illustrating a semiconductor apparatus 10 according to the present exemplary embodiment. FIG. 1 illustrates the semiconductor apparatus 10 corresponding to one chip. The semiconductor apparatus 10 has, for example, holes 20 for exposing pad portions 30 for external connection on its periphery. The semiconductor apparatus 10 includes a moisture-resistant structure 50 between the pad portions 30 and a chip end portion 60 as the periphery of the chip portion.

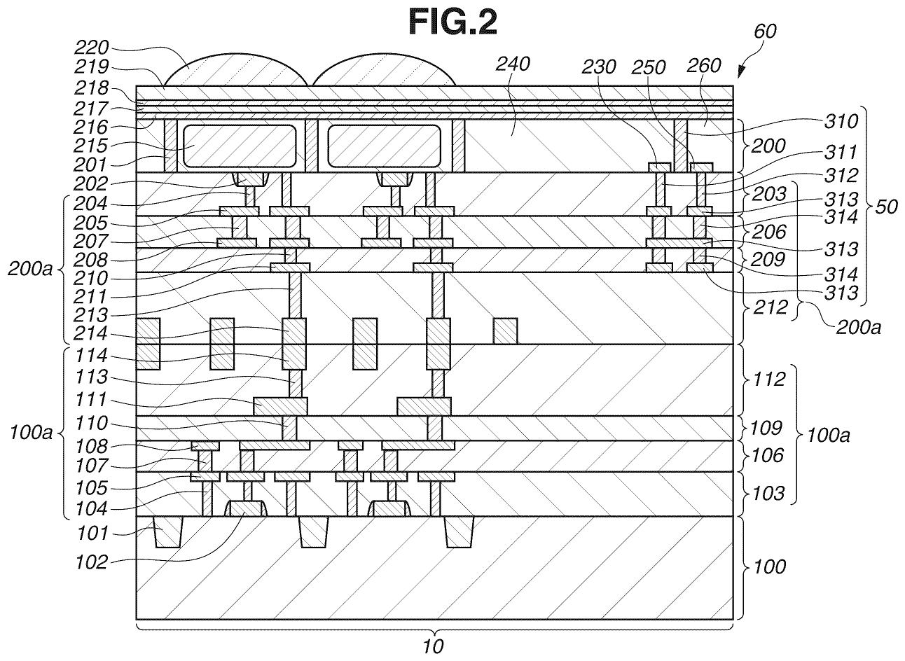

FIG. 2 is a cross-sectional view illustrating the semiconductor apparatus 10 taken along the A-A′ line, i.e., the proximity of the moisture-resistant structure 50 according to the present exemplary embodiment. The semiconductor apparatus 10 is a layered structure formed of semiconductor layers 100 and 200 being layered. Between the semiconductor layers 100 and 200, wiring structures 100a and 200a are provided.

The wiring structure 100a includes an insulating film 103, plugs 104, a wiring layer 105, an insulating film 106, a wiring layer 108, via plugs 107, an insulating film 109, via plugs 110, a wiring layer 111, an insulating film 112, bonding vias 113, and bonding metals 114.

The semiconductor layer 100 is provided with element insulators 101, and gate electrodes 102 of a plurality of transistors. The element insulators 101 have, for example, a Shallow Trench Isolation (STI) structure and define element regions (active region) of the semiconductor layer 100.

The wiring structure 200a includes an insulating film 203, plugs 204, a wiring layer 205, an insulating film 206, via plugs 207, a wiring layer 208, an insulating film 209, via plugs 210, a wiring layer 211, an insulating film 212, bonding vias 213, and bonding metals 214. Further, the wiring structure 200a has a moisture-resistant structure 50 for preventing moisture from entering from the chip end portion 60.

The semiconductor layer 200 is provided with element isolators 201, gate electrodes 202 of a plurality of transistors, and photoelectric conversion members 215 for receiving incident light to generate an electric charge. The element isolators 201 have a STI structure or a Deep Trench Isolation (DTI) structure and define element regions (active region) of the semiconductor layer 200. The element isolators 201 can vertically penetrate through the semiconductor layer 200. Further, it is also suitable that the element isolators 201 does not vertically penetrate through the semiconductor layer 200. For example, the element isolator 201 can extend from the light incident surface of the semiconductor layer 200 to the facing surface without penetrating through the facing surface, or can extend from the surface facing the light incident surface of the semiconductor layer 200 to the light incident surface without penetrating through the light incident surface.

The moisture-resistant structure 50 includes a trench 310 as an insulating member vertically penetrating through the semiconductor layer 200, a plug (first plug) 311, a plug (second plug) 312, wiring layers 313, and via plugs 314. The moisture-resistant structure 50 is formed in the process of forming the plugs 204, the wiring layer 205, the via plugs 207, the wiring layer 208, the via plugs 210, and the wiring layer 211, and is disposed along the inner side of the chip end portion 60.

The plug 311 is positioned opposite to the chip end portion 60 across the trench 310. The plug 312 is positioned between the trench 310 and the chip end portion 60. The semiconductor layer 200 also includes a semiconductor region (second semiconductor region) 240 in the direction to the photoelectric conversion members 215 from the trench 310, and a semiconductor region (fourth semiconductor region) 260 in the direction to the chip end portion 60 from the trench 310. The plugs 311 and 312 each have a conductor, and the semiconductor regions 240 and 260 are electrically connected via the plugs 311 and 312, the wiring layer 313, and the via plugs 314. The semiconductor layer 200 and the plug 311 are electrically connected via a contact region (first semiconductor region) 230. Likewise, the semiconductor layer 200 and the plug 312 are electrically connected via a contact region (third semiconductor region) 250.

The light incident surface of the semiconductor layer 200 is provided with a metal oxide film 216. Typically, the metal oxide film 216 can be an aluminum oxide film. An antireflection film 217 is disposed over the metal oxide film 216. The antireflection film 217 can be a tantalum oxide film. An insulating film 218 is disposed over the antireflection film 217. The insulating film 218 can be a single layer film (a silicon oxide film, a silicon nitride film, or a silicon oxide nitride film) or a laminated layer film as a combination of these films.

A color filter 219 is disposed over the insulating film 218. A detailed illustration of the color filter 219 is omitted. A color filter corresponding to red, blue, or green is disposed in each pixel. Typically, the color filter 219 can be arranged in the Bayer array or the quad Bayer array. The color filter 19 is not limited thereto but can be a filter of the color corresponding to the complementary color. Further, a filter corresponding to infrared light can be provided. Furthermore, a pixel corresponding to the white color that transmits all of the red, green, and blue wavelengths can be provided. As an example of a pixel corresponding to the white color, there is a structure in which an insulating film is embedded in the layer of the color filter 219 without disposing a color filter material.

Microlenses 220 are disposed on the color filter 219. The microlenses 220 are not necessarily provided, and can be omitted from the structure.

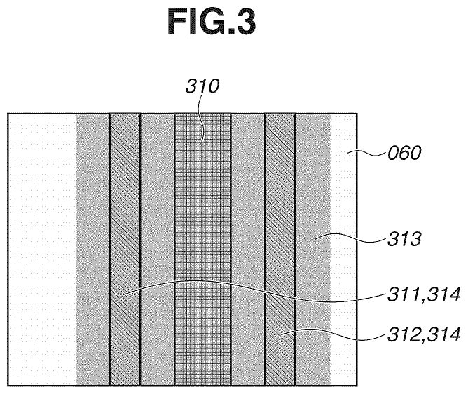

FIG. 3 is a perspective plan view illustrating a moisture-resistant structure 50 according to the present exemplary embodiment seen through from the top surface illustrated in FIG. 2. The trench 310 can be disposed along the chip end portion 60. The wiring layer 313 in the direction to the chip end portion 60 from the trench 310 is electrically connected to the wiring layer 313 opposite to the chip end portion 60 across the trench 310. The plug 311 is electrically connected to the via plugs 314 via the wiring layer 313. The plug 312 is electrically connected to the via plugs 314 via the wiring layer 313.

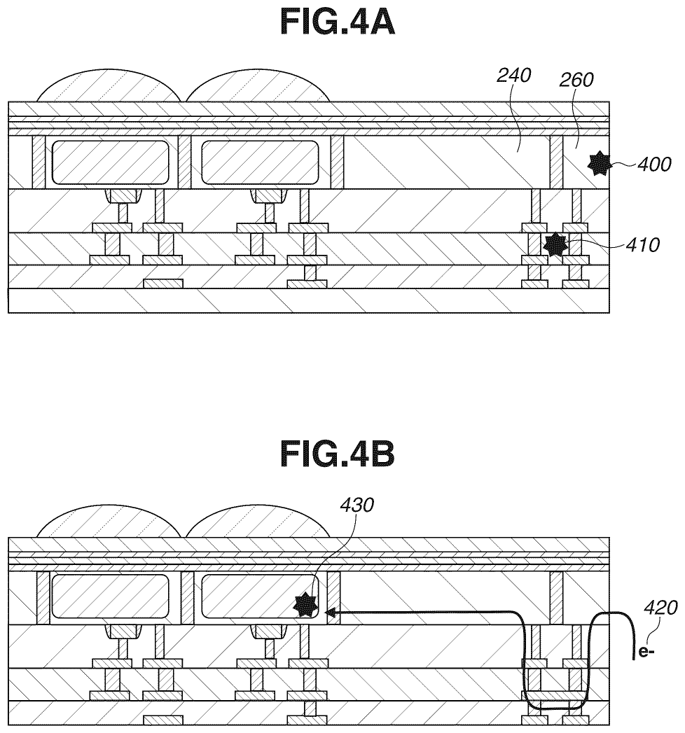

An issue resolved by the present exemplary embodiment will be described with reference to FIGS. 4A and 4B. FIG. 4A illustrates a case where the semiconductor regions 240 and 260 are not electrically connected in the moisture-resistant structure 50. In this configuration, charging that can occur in the manufacturing process and static electricity that can occur in product operation can cause a breakdown 400 of the semiconductor layer 200 and an element and a breakdown 410 of the moisture-resistant structure 50.

FIG. 4B illustrates a structure for preventing the breakdown 400 of the semiconductor layer 200 and an element and the breakdown 410 of the moisture-resistant structure 50. In FIG. 4B, the semiconductor regions 240 and 260 are electrically connected via the wiring layer 313 of the moisture-resistant structure 50. This can alleviate charging that may occur in the manufacturing process and prevent the breakdown 400 of the semiconductor layer 200 and an element and the breakdown 410 of the moisture-resistant structure 50. However, an electric charge 420 that can occur at the chip end portion 60 could move to via the moisture-resistant structure 50 the photoelectric conversion member 215, causing reduction 430 of the dark current and the sensitivity. The present exemplary embodiment restrains the reduction 430 of the dark current and sensitivity.

More specifically, the polarities of the conductivity types of the contact region 230 and the semiconductor region 240 are reversed. Likewise, the polarities of the conductivity types of the contact regions 250 and the semiconductor region 260 can be reversed. These methods can prevent the reduction 430 of the dark current and sensitivity described with reference to FIG. 4B.

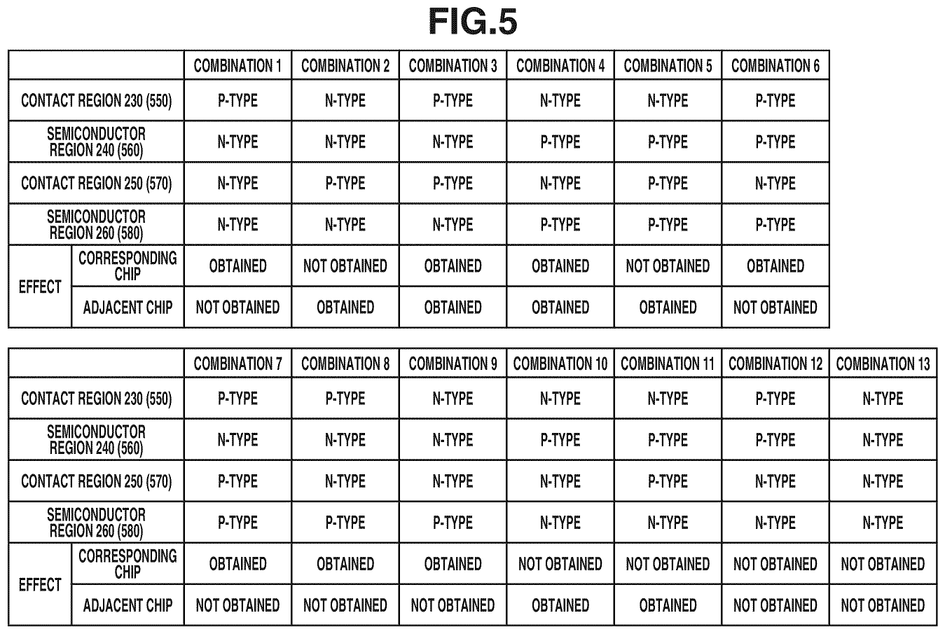

FIG. 5 illustrates combinations of the conductivity types of the contact region 230, the semiconductor region 240, the contact region 250, and the semiconductor region 260. Combinations 1 to 11 are examples of combinations that are effective against the above-described issue according to the present exemplary embodiment and a third exemplary embodiments (described below). Combinations 12 and 13 are examples of combinations that are ineffective against the above-described issue. The effect on an adjacent chip will be described below in the description of the third exemplary embodiment.

According to the present exemplary embodiment, combination 1 in FIG. 5 includes the contact region 230 of a first conductivity type (the P-type according to the present exemplary embodiment), the semiconductor region 240 of a second conductivity type (the N-type according to the present exemplary embodiment), the contact region 250 of the second conductivity type, and the semiconductor region 260 of the second conductivity type. The PN junction formed the contact region 230 and the semiconductor region 240 having opposite conductivity types allows the prevention of the electric charge 420 that may be generated at the chip end portion 60 from moving into the photoelectric conversion member 215. Likewise, the use of the combination 3, 4, 6, 7, 8, or 9 of the combinations illustrated in FIG. 5 allows the prevention of an electric charge from moving in the chip.

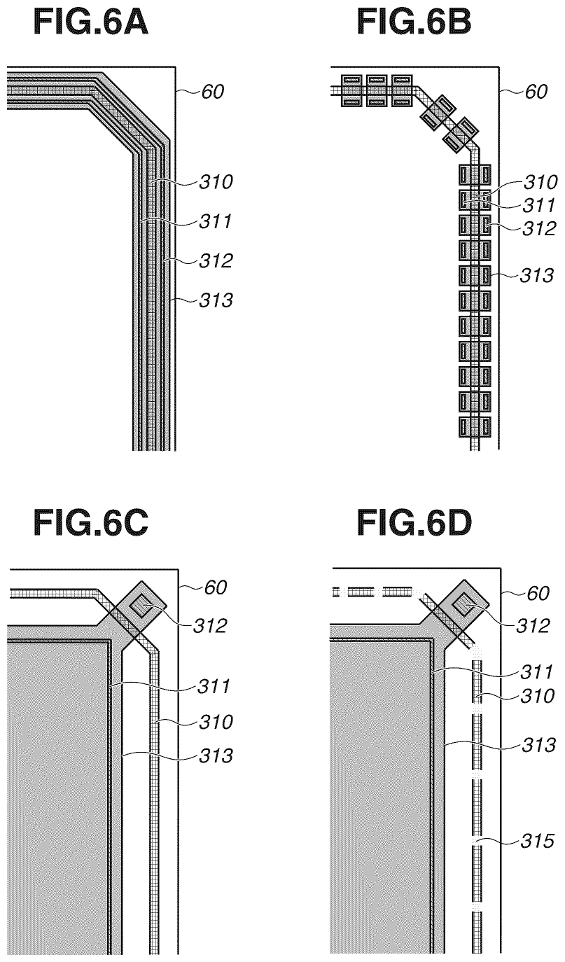

Layouts of the moisture-resistant structure 50 according to the present exemplary embodiment will be described with reference to FIGS. 6A to 6D. FIG. 6A is a schematic view illustrating a configuration in which the trench 310 is disposed in the entire outer periphery (positions along the chip end portion 60) of the semiconductor apparatus 10, and the plugs 311 and 312 are disposed along the trench 310, and the wiring layer 313 is disposed covering the plugs 311 and 312. This configuration makes it possible to favorably avoid the floating of the semiconductor layer 200 including the chip end portion 60.

The moisture-resistant structure 50 at the diagonal corners of the chip can be bent by 45 degrees as illustrated in the top views in FIGS. 6A, 6B, 6C, and 6D. This allows reduction of variations in line width and depth of the trench 310 in manufacturing. For example, if the diagonal corners of the chip are formed at right angles, the line width increases during the process of the trench 310, increase the possibility of a void occurrence, possibly causing a guard ring failure.

FIG. 6B illustrates a form in which the plugs 311 and 312 and the wiring layer 313 are intermittently electrically connected to the trench 310. If at least a part of the plugs 311 and 312 and the wiring layer 313 is electrically connected to the trench 310, the effects of the present exemplary embodiment can be produced.

FIG. 6C illustrates that connecting portions are disposed at diagonal corners alone of the chip. FIG. 6C illustrates that the connecting portions are electrically connected to the wiring layer 313. The path having higher conductivity than the semiconductor layer 200 can be used, reducing the time lag in an applied voltage, providing an effect of quickly avoiding floating.

FIG. 6D illustrates an example of a modification of FIG. 6C, i.e., a form in which the trenches 310 are intermittently disposed along the chip end portion 60. If the trenches 310 are intermittently disposed, isolation regions 315 can be formed at disconnected portions by using a technique, such as an ion injection method. The isolation regions 315 are especially effective against line width variations in processing portions where a trench 310 is bent.

The above-described configurations in FIGS. 6A to 6D can be formed with combinations of their features.

A second exemplary embodiment will be described centering on differences from the first exemplary embodiment. That is, the description according to the first exemplary embodiment is also applicable to the present exemplary embodiment.

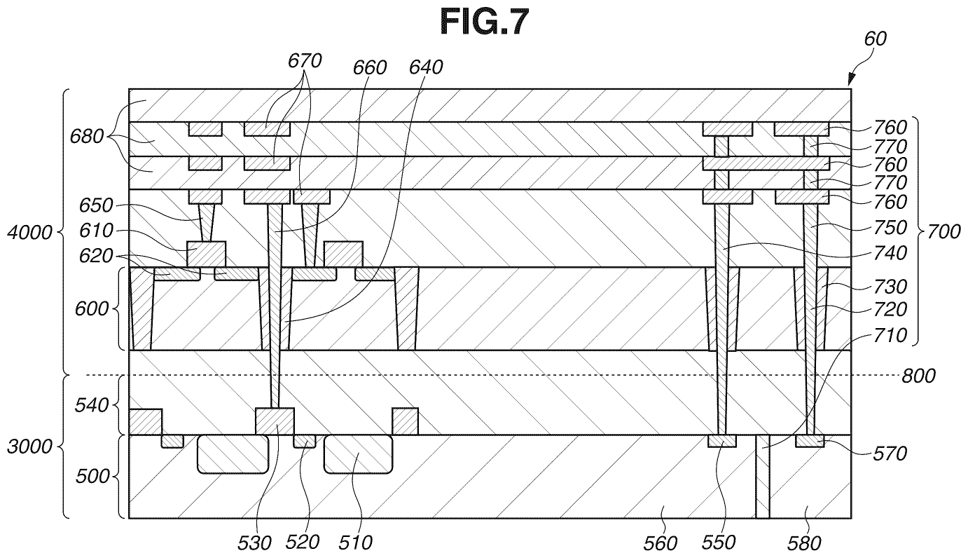

The second exemplary embodiment will be described with reference to FIG. 7. The present exemplary embodiment is an example application of the configuration of a CMOS sensor according to the first exemplary embodiment, where the pixel region and the pixel transistor region are formed on different boards.

A pixel board (first board) 3000 includes a semiconductor layer 500, photoelectric conversion members 510, floating diffusions 520, a gate electrode 530, and an insulating film 540. A pixel board transistor board (second board) 4000 includes a semiconductor layer 600, gate electrodes 610, source drain regions 620, a barrier metal 640, plugs 650, a through electrode 660, wiring layers 670, and an insulating film 680.

A moisture-resistant structure 700 includes a trench 710, a through via 720, barrier metals 730, a through electrode 740 positioned opposite to the chip end portion 60 across the trench 710, and a through electrode 750, a wiring layer 760, and via plugs 770 positioned in the direction to the chip end portion 60 from the trench 710. Each portion of the moisture-resistant structure 700 can be formed at the same time in the process of forming a pixel transistor board. The wiring of a wiring layer 760 forms electrical paths between the contact regions 550 and 570. While the potential of the wiring of the wiring layer 760 can be floated, the potential can be the ground voltage or a power voltage.

The pixel board 3000 and the pixel transistor board 4000 are bonded via a bonding surface 800, and electrically connected via the through electrodes 660, 740, and 750.

The semiconductor layer 500 includes a semiconductor region (second semiconductor region) 560 positioned in the direction to the photoelectric conversion member 510 from the trench 710, and a semiconductor region (fourth semiconductor region) 580 positioned in the direction to the chip end portion 60 from the trench 710. The semiconductor layer 500 also includes a contact region (first semiconductor region) 550 connected to the through electrode 740, and a contact region (third semiconductor region) 570 connected to the through electrode 750. The contact region 550 is formed inside the semiconductor region 560, and the contact region 570 is formed inside the semiconductor region 580.

In the above-described structure, the technique of the present disclosure can be applied by applying the polarities in the table in FIG. 5 to the polarities of the contact region 550, the semiconductor region 560, the contact region 570, and the semiconductor region 580, as in the first exemplary embodiment.

A third exemplary embodiment will be described centering on differences from the first exemplary embodiment. That is, the description according to the first exemplary embodiment is also applicable to the present exemplary embodiment.

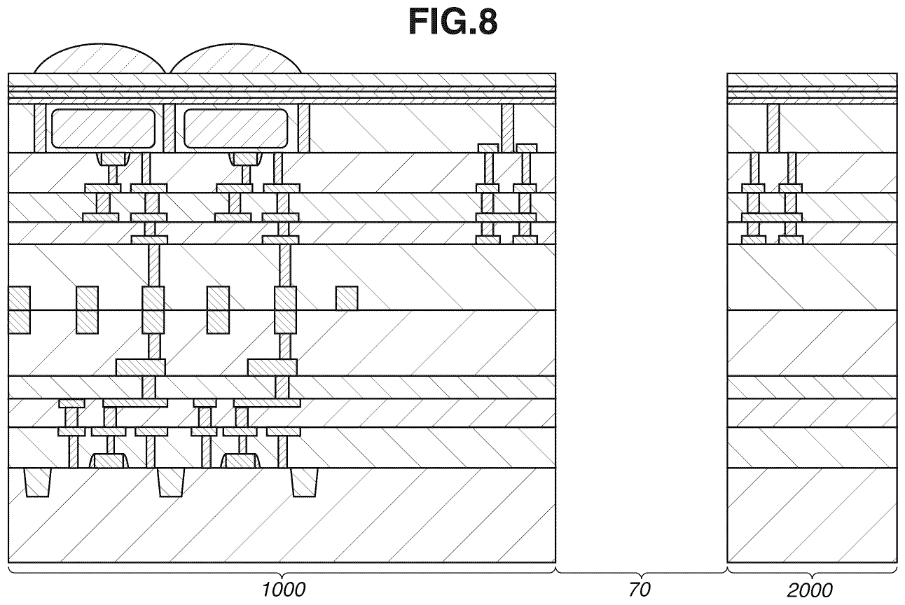

The third exemplary embodiment will be described with reference to FIG. 8. The descriptions of portions similar to those according to the first exemplary embodiment will be omitted. FIG. 8 illustrates a wafer form in which two different chips, semiconductor apparatuses 1000 and 2000, are separated with a scribe region 70. The first exemplary embodiment has been described in detail above centering on the effect in a chip form about the technique of the present disclosure. However, the technique of the present disclosure also has the effect in a wafer form.

More specifically, there are cases where a chip test in a wafer form is performed. In the test, a board potential may be shared between two adjacent chips via the scribe region 70, or a semiconductor layer potential may be shared. In this case, an electric charge can move between the chips via the scribe region 70, causing the chip test in a wafer form to be inaccurate. The moisture-resistant structure 50 according to the present exemplary embodiment of the present disclosure prevents an electric charge from moving between the chips, which can provide an accurate chip test in a wafer form.

For example, when the combination 1 to 11 of the combinations illustrated in FIG. 5 apply to the polarities of the contact region 230, the semiconductor region 240, the contact region 250, and the semiconductor region 260, the movement of an electric charge to/from the adjacent chip can be prevented.

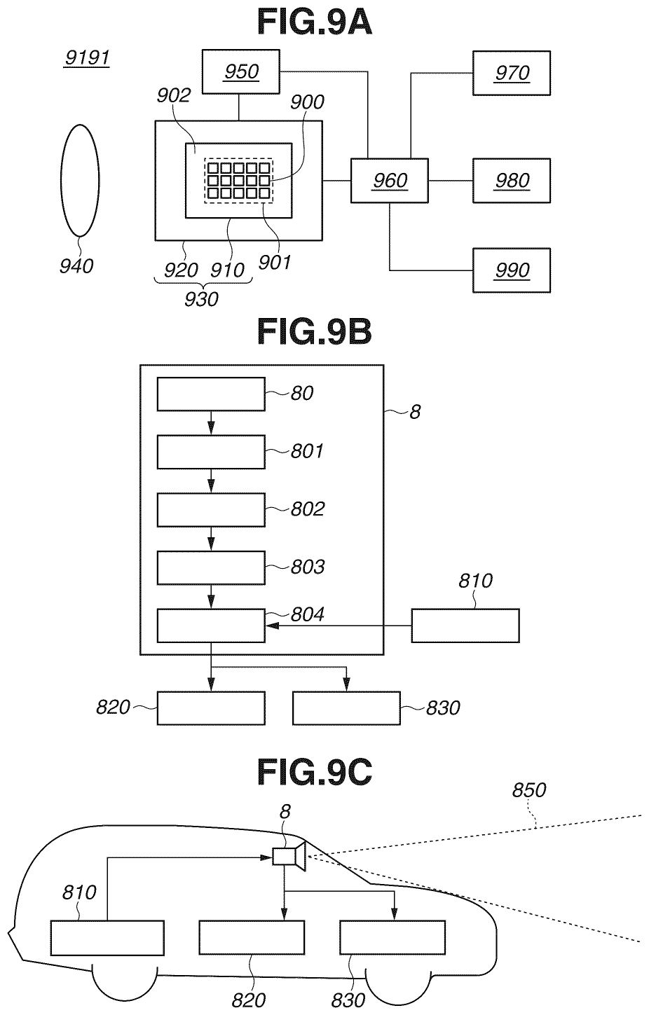

A fourth exemplary embodiment is applicable to all of the above-described exemplary embodiments. FIG. 9A is a schematic view illustrating a device 9191 including a semiconductor apparatus 930 according to the present exemplary embodiment. The semiconductor apparatus according to each of the above-described exemplary embodiments can be used as the semiconductor apparatus 930.

The device 9191 including the semiconductor apparatus 930 will be described in detail. As described above, in addition to a semiconductor apparatus 910 including a semiconductor layer 902, the semiconductor apparatus 930 can include a package 920 for containing the semiconductor apparatus 910. The package 920 can include a base member with the semiconductor apparatus 910 fixed thereon, and a cover member, such as glass facing the semiconductor apparatus 910. The package 920 can include a bonding member or bonding members, such as bonding wires and bumps for connecting a terminal or terminals disposed on the base member and a terminal or terminals disposed on the semiconductor apparatus 910.

The device 9191 can include at least an optical apparatus 940, a control apparatus 950, a processing apparatus 960, a display apparatus 970, a storage device 980, or a mechanical apparatus 990. The optical apparatus 940 is applicable to the semiconductor apparatus 930. The optical apparatus 940 is, for example, a lens, shutter, or mirror. The control apparatus 950 controls the semiconductor apparatus 930. The control apparatus 950 is, for example, a semiconductor apparatus, such as an Application Specific Integrated Circuit (ASIC).

The processing apparatus 960 processes signals output from the semiconductor apparatus 930. The processing apparatus 960 is a semiconductor apparatus, such as a central processing unit (CPU) or ASIC for configuring an analog front end (AFE) or a digital front end (DFE). The display apparatus 970 is an electroluminescence (EL) display unit and or a liquid crystal display (LCD) apparatus for displaying information (images) acquired by the semiconductor apparatus 930. The storage device 980 is a magnetic device or semiconductor device for storing information (images) acquired by the semiconductor apparatus 930. The storage device 980 is a volatile memory, such as a static random access memory (SRAM) and dynamic random access memory (DRAM), or a nonvolatile memory, such as a flash memory and hard disk drive.

The mechanical apparatus 990 includes a moving member or propulsion member, such as a motor and engine. The device 9191 displays signals output from the semiconductor apparatus 930 on the display apparatus 970 and transmits signals via a communication apparatus (not illustrated) included in the device 9191. Thus, the device 9191 further desirably includes the storage device 980 and the processing apparatus 960 in addition to a storage circuit and a calculation circuit included in the semiconductor apparatus 930. The mechanical apparatus 990 can be controlled based on signals output from the semiconductor apparatus 930.

The device 9191 is suitable for electronic apparatuses, such as information terminals having an imaging function (e.g., smart phones and wearable terminals) and cameras (e.g., lens exchangeable cameras, compact cameras, video cameras, and monitoring cameras). The mechanical apparatus 990 in a camera can drive parts of the optical apparatus 940 to perform zooming, focusing, and shutter operations. Furthermore, the mechanical apparatus 990 in a camera can move the semiconductor apparatus 930 to perform an anti-vibration operation.

The device 9191 can be a transportation device, such as a vehicle, ship, and airplane. The mechanical apparatus 990 as a transportation apparatus can be used as a moving apparatus. The device 9191 as a transportation apparatus favorably transports the semiconductor apparatus 930 and assists and/or automates driving (steering) via an imaging function. The processing apparatus 960 for assisting and/or automating driving (steering) can perform processing for operating the mechanical apparatus 990 as a moving apparatus based on information acquired by the semiconductor apparatus 930. Further, the device 9191 can be a medical apparatus, such as an endoscope, a measurement apparatus, such as a distance measurement sensor, an analytical apparatus, such as an electron microscope, an office apparatus, such as a copying machine, and an industrial apparatus, such as a robot.

The above-described exemplary embodiment makes it possible to provide favorable pixel characteristics, thus providing enhanced value of the semiconductor apparatus 930. The enhancement of value herein refers to at least the addition of a function, the improvement of performance, the improvement of characteristics, the improvement of reliability, the improvement of production yield, the reduction of environmental load, cost reduction, downsizing, or weight saving.

Thus, the semiconductor apparatus 930 according to the present exemplary embodiment to the device 9191 also provides improved value of the device 9191. For example, the semiconductor apparatus 930 mounted on a transport device provides excellent performance in imaging the outside of the transport device and measuring the external environment. As a result, a determination to mount the semiconductor apparatus according to the present exemplary embodiment to each transport device in manufacturing and selling transport devices is advantageous in improving the performance of the transport device itself. In particular, the semiconductor apparatus 930 is suitable in assisting and/or automating the driving of a transport device using information acquired by the semiconductor apparatus.

A photoelectric conversion system and a moving object according to the present exemplary embodiment will be described with reference to FIGS. 9B and 9C.

FIG. 9B illustrates an example of the photoelectric conversion system regarding an on-vehicle camera. A photoelectric conversion system 8 includes a photoelectric conversion apparatus 80. The photoelectric conversion apparatus 80 is a photoelectric conversion apparatus (imaging apparatus) according to one of the above-described exemplary embodiments. The photoelectric conversion system 8 includes an image processing unit 801 for subjecting a plurality of pieces of image data acquired by the photoelectric conversion apparatus 80 to image processing, and a parallax acquisition unit 802 for calculating a parallax (phase difference between parallax images) based on the plurality of pieces of image data acquired by the photoelectric conversion system 8.

The photoelectric conversion system 8 further includes a distance acquisition unit 803 for calculating the distance to a target object based on the calculated parallax, and a collision determination unit 804 for determining the possibility of a collision based on the calculated distance. The parallax acquisition unit 802 and the distance acquisition unit 803 are examples of distance information acquisition units for acquiring information about the distance to a target object. More specifically, the distance information includes information about the parallax, the amount of defocus, and the distance to a target object. The collision determination unit 804 can determine the possibility of a collision by using one of these pieces of distance information.

A distance information acquisition unit can be composed of specially designed hardware components or software modules. A distance information acquisition unit can also be a Field Programmable Gate Array (FPGA), an ASIC, or a combination of both.

The photoelectric conversion system 8 is connected to a vehicle information acquisition apparatus 810 to acquire vehicle information, such as the vehicle speed, yaw rate, and steering angle. The photoelectric conversion system 8 is connected to a control electronic control unit (ECU) 820 as a control apparatus that outputs control signals for generating a braking force on a vehicle based on a determination result by the collision determination unit 804. The photoelectric conversion system 8 is also connected to a warning apparatus 830 that generates an alarm to the driver based on a determination result by the collision determination unit 804.

For example, if the possibility of a collision is high based on a determination result by the collision determination unit 804, the control ECU 820 performs a vehicle control to avoid a collision and reduce damage, for example, by applying brakes, releasing the accelerator, or reducing the engine power. The warning apparatus 830 warns the user by generating an alarm sound, displaying alarm information on the screen of the car navigation system, or applying a vibration to the seat belt or steering wheel.

According to the present exemplary embodiment, the photoelectric conversion system 8 captures images of the surrounding of the vehicle, for example, images ahead of or behind the vehicle. FIG. 9C illustrates the photoelectric conversion system 8 that captures images ahead of the vehicle (imaging range 850). The vehicle information acquisition apparatus 810 transmits instructions to the photoelectric conversion system 8 or the photoelectric conversion apparatus 80. The above-described configuration provides improved accuracy of distance measurement.

While the present exemplary embodiment has been described centering on the control for avoiding a collision with other vehicles, the present exemplary embodiment is also applicable to automatic driving control for following another vehicle and automatic driving control for retaining the vehicle within the lane. The photoelectric conversion system is applicable not only to vehicles, such as the vehicle of the user, but also to moving objects (moving apparatuses), such as vessels, airplanes, and industrial robots. For example, the photoelectric conversion system can include a moving object including the photoelectric conversion apparatus according to each exemplary embodiment and a control unit for controlling the movement of the moving object by using signals output by the photoelectric conversion apparatus. In addition, the photoelectric conversion system is applicable not only to moving objects but also to intelligent transport systems (ITS's) and a wide range of apparatuses using object recognition.

### Other Exemplary Embodiments

The above-described exemplary embodiments of the present disclosure are merely examples illustrated of embodying the present disclosure, and are not to be interpreted as restrictive on the technical scope of the present disclosure. The present disclosure can be embodied in diverse forms without departing from the technical concepts or main characteristics thereof. For example, any combination of elements of the above-described exemplary embodiments is also included in the scope of the present disclosure.

The above-described exemplary embodiments can be suitably modified without departing from the technical concept thereof. The disclosure of the present specification includes not only the descriptions of the present specification but also all of the contents prehensible from the present specification and the drawings attached to the present specification.

According to at least one exemplary embodiment of the present disclosure, a semiconductor apparatus with improved reliability against static electricity can be provided.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-200144, filed Nov. 27, 2023, which is hereby incorporated by reference herein in its entirety.

What is claimed is:

1. A semiconductor apparatus comprising:
a semiconductor layer comprising a first surface, an element region, and an end portion;
a wiring layer disposed on the side of the first surface;
an insulating member disposed between the element region and the end portion in a planar view with respect to the first surface, and configured to penetrate through the semiconductor layer;
a first plug including a conductor, disposed between the first surface and the wiring layer, and disposed between the element region and the insulating member in a planar view with respect to the first surface; and
a second plug including a conductor, disposed between the first surface and the wiring layer and disposed between the end portion and the insulating member in a planar view with respect to the first surface;
wherein the first plug and the second plug are electrically connected via the wiring layer,
wherein the conductor included in the first plug is connected to a first semiconductor region of a first conductivity type disposed in the semiconductor layer, and
wherein the first semiconductor region is disposed inside a second semiconductor region of a second conductivity type disposed in the semiconductor layer.

2. The semiconductor apparatus according to claim 1, wherein a part of the semiconductor layer is continuously disposed from the insulating member to the end portion.

3. The semiconductor apparatus according to claim 2, wherein the part of the semiconductor layer overlaps with at least a part of the second plug in a planar view with respect to the first surface.

4. The semiconductor apparatus according to claim 1, wherein, along the first surface, the first semiconductor region has one end portion and another end portion, and at least one of the one end portion or the other end portion is in contact with the semiconductor layer.

5. The semiconductor apparatus according to claim 1,
wherein the conductor included in the second plug is connected to a third semiconductor region of the second conductivity type disposed in the semiconductor layer, and
wherein the third semiconductor region is disposed inside a fourth semiconductor region of the second conductivity type disposed in the semiconductor layer.

6. The semiconductor apparatus according to claim 1, further comprising a first board provided with the semiconductor layer, and a second board provided with a semiconductor layer different from the semiconductor layer,
wherein the element region included in the semiconductor layer includes a photoelectric conversion member configured to receive incident light to generate an electric charge,
wherein the different semiconductor layer includes a pixel transistor for outputting a signal based on the electric charge, and
wherein the first board and the second board are bonded on a bonding surface.

7. The semiconductor apparatus according to claim 1, wherein the insulating member is disposed at at least a part of an outer periphery of the semiconductor apparatus in a planar view with respect to the first surface.

8. The semiconductor apparatus according to claim 7, wherein the insulating member is intermittently disposed over the entire outer periphery in a planar view with respect to the first surface.

9. The semiconductor apparatus according to claim 7, wherein the insulating member is disposed over the entire outer periphery in a planar view with respect to the first surface.

10. The semiconductor apparatus according to claim 7, wherein the insulating member is at least partially connected to the first plug, the second plug, and the wiring layer in a planar view with respect to the first surface.

11. The semiconductor apparatus according to claim 10, wherein the insulating member is connected to the first plug, the second plug, and the wiring layer at diagonal portions of the semiconductor apparatus in a planar view with respect to the first surface.

12. The semiconductor apparatus according to claim 9, wherein the insulating member is intermittently connected to the first plug, the second plug, and the wiring layer over the entire periphery in a planar view with respect to the first surface.

13. The semiconductor apparatus according to claim 9, wherein the insulating member is connected to the first plug, the second plug and, the wiring layer over the entire periphery in a planar view with respect to the first surface.

14. A method for manufacturing a semiconductor apparatus, the method comprising:
forming an element region in a semiconductor layer having a first surface;
forming a first semiconductor region of a first conductivity type inside a second semiconductor region of a second conductivity type included in the semiconductor layer;
forming an insulating member penetrating through the semiconductor layer between the element region and an end portion of the semiconductor layer in a planar view with respect to the first surface;
forming a first plug including a conductor in a region between the element region and the insulating member in a planar view with respect to the first surface such that the first plug is in contact with the first semiconductor region;
forming a second plug including a conductor in a region between the end portion of the semiconductor layer and the insulating member in a planar view with respect to the first surface, on the side of the first surface; and
electrically connecting the first and the second plugs via a wiring layer.

15. The method for manufacturing a semiconductor apparatus according to claim 14, wherein a part of the semiconductor layer is continuously disposed from the insulating member to the end portion.

16. The method for manufacturing a semiconductor apparatus according to claim 15, wherein the part of the semiconductor layer overlaps with at least a part of the second plug in a planar view with respect to the first surface.

17. The method for manufacturing a semiconductor apparatus according to claim 14, wherein, along the first surface, the first semiconductor region has one end portion and another end portion, and at least one of the one end portion or the other end portion is in contact with the semiconductor layer.

18. A device comprising the semiconductor apparatus according to claim 1, the device further comprising at least one of:
an optical apparatus applicable to the semiconductor apparatus;
a control apparatus configured to control the semiconductor apparatus;
a processing apparatus configured to process a signal output from the semiconductor apparatus;
a display apparatus configured to display information acquired by the semiconductor apparatus;
a storage device configured to store the information acquired by the semiconductor apparatus; or
a mechanical apparatus configured to operate based on the information acquired by the semiconductor apparatus.
